(19) United States
(12) Patent Application Publication
(10) Pub. No.: US 2023/0335573 A1
(43) Pub. Date: Oct. 19, 2023

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventors: YASUHISA TOCHIGI, TOKYO (JP); TAIICHIRO WATANABE, KANAGAWA (JP); FUMIHIKO KOGA, KANAGAWA (JP)

(21) Appl. No.: 18/002,599

(22) PCT Filed: Jun. 3, 2021
(86) PCT No.: PCT/JP2021/021277

§ 371 Date: Dec. 20, 2022

(30) Foreign Application Priority Data
Jun. 29, 2020 (JP) 2020-111983

(51) Int. Cl. H01L 27/146

(52) U.S. Cl. CPC H01L 27/14636; H01L 27/14612

(57) ABSTRACT

A photodetection device includes: a photoelectric conversion layer provided in a first substrate; a diffusion region provided in a second substrate attached to the first substrate, the diffusion region storing electric charge resulting from photoelectric conversion at the photoelectric conversion layer; and a coupling section having a multilayer structure including a via and a wiring layer, the coupling section being provided to extend from the first substrate to the second substrate and electrically coupling the photoelectric conversion layer and the diffusion region. The coupling section is provided in a manner in which, as viewed in a plane from a direction normal to a principal surface of each of the first substrate and the second substrate, a plane region of each layer is included in a plane region of a layer that is largest in plane region.

### TECHNICAL FIELD

The present disclosure relates to a photodetection device, and to an electronic apparatus.

### BACKGROUND ART

In recent years, a photodetection device of a stacked type has been proposed that includes a plurality of substrates attached to each other (for example, see PTL 1). In such a photodetection device of the stacked type, electric charge that results from photoelectric conversion at a photoelectric conversion layer provided in a first substrate is transmitted to a second substrate, and the electric charge is converted into a detection signal at a readout circuit provided in the second substrate.

### CITATION LIST

### Patent Literature

PTL 1: International Publication No. WO2017/150167

### SUMMARY OF THE INVENTION

In such a photodetection device, a transmission path of electric charge to a readout circuit tends to be long. Accordingly, for the photodetection device, it is desired to reduce noise of a detection signal by reducing a wiring capacitance of a wiring line involved in the transmission of the electric charge.

It is thus desirable to provide a photodetection device and an electronic apparatus that each achieve a further reduction in noise of the detection signal.

A photodetection device according to one embodiment of the present disclosure includes: a photoelectric conversion layer provided in a first substrate; a diffusion region provided in a second substrate attached to the first substrate, the diffusion region storing electric charge resulting from photoelectric conversion at the photoelectric conversion layer; and a coupling section having a multilayer structure including a via and a wiring layer, the coupling section being provided to extend from the first substrate to the second substrate and electrically coupling the photoelectric conversion layer and the diffusion region. The coupling section is provided in a manner in which, as viewed in a plane from a direction normal to a principal surface of each of the first substrate and the second substrate, a plane region of each layer is included in a plane region of a layer that is largest in plane region.

An electronic apparatus according to one embodiment of the present disclosure includes: a photoelectric conversion layer provided in a first substrate; a diffusion region provided in a second substrate attached to the first substrate, the diffusion region storing electric charge resulting from photoelectric conversion at the photoelectric conversion layer; and a coupling section having a multilayer structure including a via and a wiring layer, the coupling section being provided to extend from the first substrate to the second substrate and electrically coupling the photoelectric conversion layer and the diffusion region. The coupling section is provided in a manner in which, as viewed in a plane from a direction normal to a principal surface of each of the first substrate and the second substrate, a plane region of each layer is included in a plane region of a layer that is largest in plane region.

In the photodetection device and the electronic apparatus according to one embodiment of the present disclosure, the photoelectric conversion layer provided in the first substrate and the diffusion region provided in the second substrate attached to the first substrate are electrically coupled by the coupling section that is provided in a manner in which, as viewed in a plane from the direction normal to the principal surface of each of the first substrate and the second substrate, the plane region of each layer is included in the plane region of the layer that is largest in plane region. This results in a further reduction in wiring capacitance to be generated in the coupling section that transmits the electric charge from the photoelectric conversion layer to the diffusion region, for example.

### BRIEF DESCRIPTION OF DRAWING

FIG. 1 is a schematic planar diagram describing an overall configuration of a photodetection device according to one embodiment of the present disclosure.

FIG. 2 is a circuit diagram illustrating a configuration of an equivalent circuit of a sensor pixel.

FIG. 3 is a vertical cross-sectional diagram illustrating a cross-sectional configuration of the photodetection device.

FIG. 4A is a vertical cross-sectional diagram illustrating a cross-sectional configuration of one example of a coupling section.

FIG. 4B is a planar diagram illustrating a planar configuration of the one example of the coupling section.

FIG. 5A is a vertical cross-sectional diagram illustrating a cross-sectional configuration of another example of the coupling section.

FIG. 5B is a planar diagram illustrating a planar configuration of the other example of the coupling section.

FIG. 6A is a schematic planar diagram illustrating a planar shape of each of wiring layers provided in a second substrate.

FIG. 6B is a schematic planar diagram illustrating the planar shape of each of the wiring layers provided in the second substrate.

FIG. 6C is a schematic planar diagram illustrating the planar shape of each of the wiring layers provided in the second substrate.

FIG. 6D is a schematic planar diagram illustrating the planar shape of each of the wiring layers provided in the second substrate.

FIG. 7 is a schematic vertical cross-sectional diagram illustrating a configuration of a coupling section according to a first modification example.

FIG. 8 is a schematic vertical cross-sectional diagram illustrating a configuration of a coupling section according to a second modification example.

FIG. 9 is a circuit diagram illustrating a configuration example of an equivalent circuit of a sensor pixel according to a third modification example.

FIG. 10 is a circuit diagram illustrating a configuration example of an equivalent circuit of the sensor pixel according to the third modification example.

FIG. 11 is a circuit diagram illustrating a configuration example of an equivalent circuit of the sensor pixel according to the third modification example.

FIG. 12 is a circuit diagram illustrating a configuration example of an equivalent circuit of the sensor pixel according to the third modification example.

FIG. 13 is a block diagram illustrating an example of a schematic configuration of an imaging unit including the photodetection device according to one embodiment of the present disclosure.

FIG. 14 is a flowchart diagram illustrating an example of an imaging operation of the imaging unit.

### MODES FOR CARRYING OUT THE INVENTION

In the following, some embodiments of the present disclosure will be described in detail with reference to the drawings. It is to be noted that the embodiments described below are specific examples of the present disclosure, and the present disclosure is not limited to the following embodiments. In addition, the arrangement, dimensions, dimension ratios, and the like of components in the present disclosure are not limited to the embodiment illustrated in each drawing.

It is to be noted that the description will be given in the following order.
1. Overall Configuration
2. Configuration of Sensor Pixel
   2.1. Circuit Configuration
   2.2. Cross-sectional Configuration
   2.3. Configuration of Coupling Section
3. Modification Examples
4. Application Example

### 1. Overall Configuration

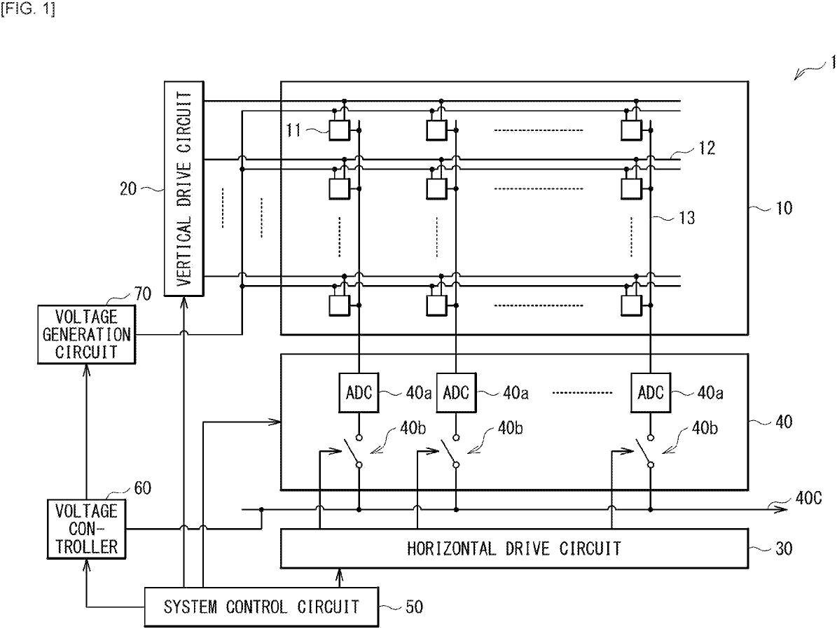

First, with reference to FIG. 1, a description will be given of an overall configuration of a photodetection device according to one embodiment of the present disclosure. FIG. 1 is a schematic planar diagram describing the overall configuration of a photodetection device 1 according to the present embodiment.

As illustrated in FIG. 1, the photodetection device 1 is a photodetection device that detects entering light with use of a plurality of sensor pixels 11 arranged two-dimensionally in a matrix (that is, in a matrix shape) in a pixel array section 10. The photodetection device 1 is able to detect infrared light having a wavelength of 800 nm or more.

The sensor pixels 11 each include a photoelectric conversion layer having sensitivity to infrared light having a wavelength of 800 nm or more. Examples of the photoelectric conversion layer that is able to photoelectrically convert such infrared light (for example, infrared light having a wavelength of 900 nm to 1700 nm) include a photoelectric conversion layer including a Group III-V compound semiconductor, such as InGaP, InAlP, InGaAs, or InAlAs.

The sensor pixels 11 are each driven by a vertical drive circuit 20, a horizontal drive circuit 30, a horizontal selection circuit 40, a system control circuit 50, a voltage controller 60, and a voltage generation circuit 70 provided around the pixel array section 10. Under the control by these peripheral circuits, each of the sensor pixels 11 is able to output a detection signal corresponding to an amount of received light.

In accordance with a master clock, the system control circuit 50 generates a clock signal, a control signal, and the like serving as a reference for operations of the vertical drive circuit 20, the horizontal drive circuit 30, the horizontal selection circuit 40, the voltage controller 60, etc. The system control circuit 50 supplies the generated clock signal and control signal to the vertical drive circuit 20, the horizontal selection circuit 40, the voltage controller 60, etc.

On the basis of the detection signal obtained from the sensor pixel 11, the voltage controller 60 controls a voltage to be applied to the photoelectric conversion layer of the sensor pixel 11. This makes it possible for the voltage controller 60 to perform feedback control to thereby control the voltage to be applied to the photoelectric conversion layer of the sensor pixel 11, thus making it possible to improve an intensity and accuracy of the detection signal to be obtained from the sensor pixel 11. Specifically, the voltage controller 60 outputs a control signal to control the voltage to be applied to the photoelectric conversion layer to the voltage generation circuit 70. On the basis of the control signal received, the voltage generation circuit 70 generates an analog voltage to be applied to both electrodes of the photoelectric conversion layer. The generated analog voltage is applied to both electrodes of the photoelectric conversion layer of each of the sensor pixels 11 via a power supply line.

The vertical drive circuit 20 includes, for example, a shift register, etc., and controls driving of the plurality of sensor pixels 11 on a row-by-row basis via a plurality of pixel drive lines 12.

The horizontal selection circuit 40 includes an ADC 40a and a switch element 40b provided for each pixel column (or vertical signal line 13) of the pixel array section 10, for example. The ADC 40a is an analog-to-digital converter that performs an AD (Analog-to-Digital) conversion of the detection signal outputted from each of the sensor pixels 11. The vertical signal line 13 is coupled to an input end of the ADC 40a, and the switch element 40b is coupled to an output end of the ADC 40a. It is to be noted that the ADC 40a is provided to enable an analog range to be varied, and sets the analog range on the basis of a range setting value inputted from outside.

The horizontal drive circuit 30 includes, for example, a shift register, etc., and drives the respective switch elements 40b of the horizontal selection circuit 40 in order. By driving the respective switch elements 40b in order, the horizontal drive circuit 30 is able to output respective detection signals (digital values) transmitted via the respective vertical signal lines 13 to the horizontal signal line 40c in order. It is to be noted that the detection signals outputted to the horizontal signal line 40c are outputted to an unillustrated DSP (Digital Signal Processor) circuit or the like, for example.

### 2. Configuration of Sensor Pixel

### (2.1. Circuit Configuration)

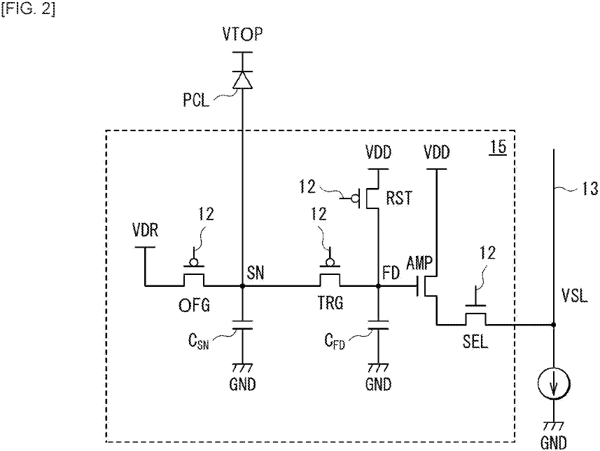

Next, with reference to FIG. 2, a description will be given of a circuit configuration of the sensor pixel 11. FIG. 2 is a circuit diagram illustrating a configuration of an equivalent circuit of the sensor pixel 11.

As illustrated in FIG. 2, the sensor pixel 11 includes a photoelectric conversion layer PCL that converts entering light into electric charge, a diffusion region SN that stores the electric charge resulting from the photoelectric conversion, and a readout circuit 15 that outputs a detection signal on the basis of the electric charge resulting from the photoelectric conversion.

The photoelectric conversion layer PCL absorbs light having a predetermined wavelength (for example, infrared light having a wavelength of 900 nm to 1700 nm) and generates electric charge. One of the electrodes (for example, a cathode) of the photoelectric conversion layer PCL is electrically coupled to the diffusion region SN, and another of the electrodes (for example, an anode) of the photoelectric conversion layer PCL is coupled to a power supply line VTOP.

The photoelectric conversion layer PCL may include a Group III-V compound semiconductor. For example, the photoelectric conversion layer PCL may include a Group III-V compound semiconductor, such as InGaP, InAlP, InGaAs, or InAlAs. It is to be noted that the photoelectric conversion layer PCL may include a compound semiconductor having a chalcopyrite structure, amorphous silicon (a-Si), germanium (Ge), a quantum dot, an organic photoelectric conversion material, or the like, instead of the Group III-V compound semiconductor described above.

The diffusion region SN is region configured by introducing an electrically-conductive impurity into a semiconductor substrate or the like, and stores the electric charge resulting from the photoelectric conversion at the photoelectric conversion layer PCL. To the diffusion region SN, a source of a transfer transistor TRG is electrically coupled, and also a source of a discharge transistor OFG is electrically coupled.

The electric charge stored in the diffusion region SN is transferred to a floating diffusion FD via the transfer transistor TRG. In the photodetection device 1 according to the present embodiment, the transfer of the electric charge from the diffusion region SN to the floating diffusion FD is performed at all the sensor pixels 11 simultaneously. This makes it possible to achieve exposure of a global shutter system, that is, simultaneous exposure of all pixels.

The readout circuit 15 includes, for example, the discharge transistor OFG, the transfer transistor TRG, the floating diffusion FD, a reset transistor RST, a selection transistor SEL, and an amplification transistor AMP.

The floating diffusion FD is a region configured by introducing an electrically-conductive impurity into a semiconductor substrate or the like. The discharge transistor OFG, the transfer transistor TRG, the reset transistor RST, the selection transistor SEL, and the amplification transistor AMP are MOS (Metal-Oxide-Semiconductor) transistors, for example.

On the basis of a control signal applied to a gate electrode, the discharge transistor OGF discharges the electric charge stored in the diffusion region SN and initializes (resets) a state of the diffusion region SN. The source of the discharge transistor OFG is electrically coupled to the diffusion region SN, and a drain of the discharge transistor OFG is electrically coupled to a power supply line VDR.

The transfer transistor TRG is provided between the diffusion region SN and the floating diffusion FD, and transfers, on the basis of a control signal applied to a gate electrode, the electric charge stored in the diffusion region SN to the floating diffusion FD. The gate electrode of the transfer transistor TRG is electrically coupled to the pixel drive line 12, the source of the transfer transistor TRG is electrically coupled to the diffusion region SN, and a drain of the transfer transistor TRG is electrically coupled to the floating diffusion FD.

The floating diffusion FD is a floating diffusion region that temporarily stores the electric charge transferred from the diffusion region SN via the transfer transistor TRG. For example, the vertical signal line 13 is electrically coupled to the floating diffusion FD via the amplification transistor AMP and the selection transistor SEL.

The reset transistor RST initializes (resets) a potential of the floating diffusion FD to a predetermined potential. A gate electrode of the reset transistor RST is electrically coupled to the pixel drive line 12, a source of the reset transistor RST is electrically coupled to the floating diffusion FD, and a drain of the reset transistor RST is electrically coupled to a power supply line VDD. Upon turning on, the reset transistor RST initializes the potential of the floating diffusion FD to a potential of the power supply line VDD. It is to be noted that the potential of the power supply line VDD may be the same as or different from a potential of the power supply line VDR.

The amplification transistor AMP generates a detection signal of a voltage corresponding to a level of the electric charge held by the floating diffusion FD. Specifically, the amplification transistor AMP configures an amplifier of a source follower type, for example, and outputs a detection signal of a voltage corresponding to a level of the electric charge generated in the photoelectric conversion layer PCL. The amplification transistor AMP is thus able to generate, as the detection signal, a signal of a voltage corresponding to the amount of received light at the sensor pixel 11.

A gate electrode of the amplification transistor AMP is electrically coupled to the floating diffusion FD, a source of the amplification transistor AMP is electrically coupled to a drain of the selection transistor SEL, and a source of the amplification transistor AMP is electrically coupled to the power supply line VDD. Upon turning-on of the selection transistor SEL, the amplification transistor AMP amplifies the potential of the floating diffusion FD, and outputs a voltage corresponding to the potential of the floating diffusion FD to the vertical signal line (VSL) 13.

The selection transistor SEL controls an output timing of the detection signal from the readout circuit 15. A gate of the selection transistor SEL is electrically coupled to the pixel drive line 12. A source of the selection transistor SEL is electrically coupled to vertical signal line 13, and the drain of the selection transistor SEL is electrically coupled to the source of the amplification transistor AMP.

It is to be noted that the selection transistor SEL may be provided between the power supply line VDD and the amplification transistor AMP. In such a case, the gate electrode of the selection transistor SEL is electrically coupled to the pixel drive line 12, the drain of the selection transistor SEL is electrically coupled to the power supply line VDD, and the source of the selection transistor SEL is electrically coupled to the drain of the amplification transistor AMP. Meanwhile, the source of the amplification transistor AMP is electrically coupled to the vertical signal line 13, and the voltage corresponding to the potential of the floating diffusion FD is outputted from the source of the amplification transistor AMP to the vertical signal line (VSL) 13.

### (2.2. Cross-sectional Configuration)

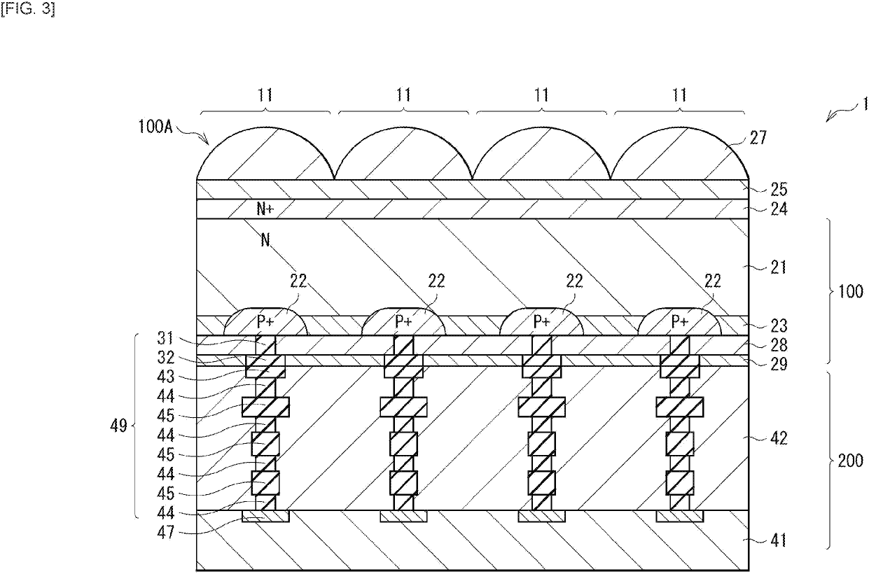

Next, with reference to FIG. 3, a description will be given of a cross-sectional configuration of the sensor pixel 11. FIG. 3 is a vertical cross-sectional diagram illustrating a cross-sectional configuration of the photodetection device 1.

As illustrated in FIG. 3, a first substrate 100 includes a photoelectric conversion layer 21 including a p-type compound semiconductor. Specifically, the photoelectric conversion layer 21 includes n-type InGaAs and is provided to extend over the entire pixel array section 10. It is to be noted that the photoelectric conversion layer 21 may include germanium (Ge), an organic photoelectric conversion material, or the like instead of the n-type InGaAs.

The first substrate 100 further includes a contact layer 22 including a p-type compound semiconductor and provided on a surface of the photoelectric conversion layer 21 on a second substrate 200 side. Specifically, the contact layer 22 includes highly concentrated p-type InGaAs and is provided for each sensor pixel 11. The contact layer 22 serves as one of electrodes to apply a voltage to the photoelectric conversion layer 21. The contact layer 22 is thus able to extract the electric charge generated in the photoelectric conversion layer 21.

The first substrate 100 further includes a separation layer 23 including an n-type compound semiconductor and separating the contact layers 22 from each other. Specifically, the separation layer 23 includes n-type InP and is provided in the same layer as the contact layers 22. For example, the separation layer 23 may be provided to surround the contact layers 22 that are provided in an island-shape for the respective sensor pixels 11.

The first substrate 100 further includes a barrier layer 24 including an n-type compound semiconductor and provided on a surface of the photoelectric conversion layer 21 on a light-receiving surface 100A side. Specifically, the barrier layer 24 includes an n-type compound semiconductor having a higher concentration than in the photoelectric conversion layer 21, and is provided to extend over the entire photoelectric conversion layer 21. For example, the barrier layer 24 may be provided using n-type InGaAs, n-type InP, or n-type InAlAs having a higher concentration than in the photoelectric conversion layer 21. This makes it possible for the barrier layer 24 to suppress a backflow of the electric charge generated in the photoelectric conversion layer 21.

In addition, the barrier layer 24 also serves as another of the electrodes to apply a voltage to the photoelectric conversion layer 21. In other words, the voltage is applied to the photoelectric conversion layer 21 from each of the contact layer 22 and the barrier layer 24 that sandwich the photoelectric conversion layer 21 from above and below.

An antireflection film 25 is further provided on a surface of the barrier layer 24 on the light-receiving surface 100A side. The antireflection film 25 includes, for example, silicon nitride (SiN), hafnium oxide (HfO₂), aluminum oxide (Al₂O₃), zirconium oxide (ZrO₂), tantalum oxide (Ta₂Ta₅), titanium oxide (TiO₂), or the like. The antireflection film 25 is able to prevent reflection of entering light by using a difference in refractive index between the barrier layer 24 and the antireflection film 25.

An on-chip lens 27 is further provided on a surface of the antireflection film 25 on the light-receiving surface 100A side. One on-chip lens 27 is provided for each sensor pixel 11. The on-chip lens 27 is able to concentrate entering light onto a middle of the sensor pixel 11.

The first substrate 100 further incudes a passivation layer 28 and an insulating layer 29 provided on a second substrate 200 side of the contact layer 22 and the separation layer 23. The passivation layer 28 and the insulating layer 29 include, for example, silicon oxide (SiOₓ), silicon nitride (SiN), silicon oxynitride (SiON), or the like.

In addition, the passivation layer 28 is provided with a coupling electrode 31 that penetrates the passivation layer 28 and electrically couples to the contact layer 22. The insulating layer 29 is provided with a metal bonding layer 32 that penetrates the insulating layer 29 and electrically couples to the coupling electrode 31. The coupling electrode 31 and the metal bonding layer 32 each include an electrically-conductive material such as palladium (Pd), titanium (Ti), titanium nitride (TiN), tungsten (W), nickel (Ni), aluminum (Al), copper (Cu), platinum (Pt), silver (Ag), or gold (Au). One coupling electrode 31 and one metal bonding layer 32 are provided for each sensor pixel 11.

The second substrate 200 includes a semiconductor substrate 41 and an interlayer insulating layer 42. The semiconductor substrate 41 is a silicon (Si) substrate, for example. The interlayer insulating layer 42 includes an insulating material such as silicon oxide (SiOₓ), silicon nitride (SiN), or silicon oxynitride (SiON), and is provided to be stacked on the semiconductor substrate 41. The second substrate 200 is provided to be attached to the first substrate 100 in a manner in which the interlayer insulating layer 42 faces the insulating layer 29 of the first substrate 100.

The semiconductor layer 41 is provided with a diffusion region 47 into which an electrically-conductive impurity is introduced. In the interlayer insulating layer 42, a metal bonding layer 43, a plurality of wiring layers 45, and a plurality of vias 44 are provided to be electrically coupled to each other from a first substrate 100 side. The contact layer 22, the coupling electrode 31, the metal bonding layer 32, the metal bonding layer 43, the plurality of wiring layers 45, and the plurality of vias 44 (these components will be collectively referred to also as a coupling section 49) are able to electrically couple the photoelectric conversion layer 21 provided in the first substrate 100 and the diffusion region 47 provided in the semiconductor substrate 41.

The metal bonding layer 43 is bonded to the metal bonding layer 32 of the first substrate 100 and is thereby electrically coupled to the metal bonding layer 32. Specifically, the metal bonding layer 32 in the insulating layer 29 and the metal bonding layer 43 in the second substrate 200 are provided to be so exposed in respective surfaces of the first substrate 100 and the second substrate 200 as to be brought into contact with each other when the first substrate 100 and the second substrate 200 are attached to each other. It is thus possible to electrically couple the metal bonding layer 32 and the metal bonding layer 43 by bonding respective metals to each other by heat treatment. In such a case, it is desirable that the metal bonding layer 32 and the metal bonding layer 43 each include copper (Cu), and form a Cu-Cu direct bonding structure. It is to be noted that the metal bonding layer 43 may be electrically coupled to the metal bonding layer 32 of the first substrate 100 by using a bump structure, instead of the Cu-Cu direct bonding structure.

The plurality of wiring lines 45 and the plurality of vias 44 each include an electrically-conductive material such as palladium (Pd), titanium (Ti), titanium nitride (TiN), tungsten (W), nickel (Ni), aluminum (Al), copper (Cu), platinum (Pt), silver (Ag), or gold (Au).

The electric charge generated in the photoelectric conversion layer 21 is transmitted to the diffusion region 47 via the coupling section 49, and is stored in the diffusion region 47. The electric charge stored in the diffusion region 47 is transferred to the readout circuit 15 at a subsequent stage via the unillustrated transfer transistor TRG. The photodetection device 1 allows the electric charge generated in the photoelectric conversion layer 21 to be stored in the diffusion regions 47 separated from each other for the individual sensor pixels 11. Accordingly, it is possible to suppress a crosstalk between adjacent sensor pixels 11.

### (2.3. Configuration of Coupling Section)

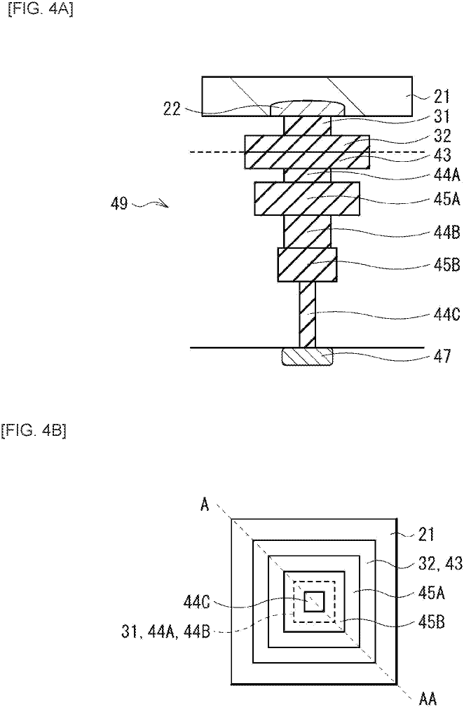

Now, with reference to FIGS. 4A to 6D, a more specific description will be given of a configuration of the coupling section 49 provided in the photodetection device 1 according to the present embodiment.

In the photodetection device 1 according to the present embodiment, the coupling section 49 that electrically couples the photoelectric conversion layer 21 of the first substrate 100 and the diffusion region 47 of the second substrate 200 is provided in a manner in which, as viewed in a plane from a direction normal to a principal surface of each of the first substrate 100 and the second substrate 200, a plane region of each layer is included in a plane region of a layer that is largest in plane region. Specifically, the contact layer 22, the coupling electrode 31, the metal bonding layer 32, the metal bonding layer 43, the plurality of wiring layer 45, and the plurality of vias 44 which electrically couple the photoelectric conversion layer 21 and the diffusion region 47 are provided to be included in the plane region of a layer, among them, that is largest in plane region.

First, an example of the configuration of the coupling section 49 will be described with reference to FIGS. 4A and 4B. FIG. 4A is a vertical cross-sectional diagram illustrating a cross-sectional configuration of one example of the coupling section 49. FIG. 4B is a planar diagram illustrating a planar configuration of the one example of the coupling section 49. The cross section illustrated in FIG. 4A corresponds to a cross section taken along cut line A-AA of FIG. 4B.

As illustrated in FIG. 4A, the photoelectric conversion layer 21 is electrically coupled to the diffusion region 47 via the coupling section 49. The coupling section 49 is provided by stacking, from the photoelectric conversion layer 21 side, for example, the coupling electrode 31, the metal bonding layer 32, the metal bonding layer 43, a via 44A, a wiring layer 45A, a via 44B, a wiring layer 45B, and a via 44C substantially in series in a thickness direction of the first substrate 100 and the second substrate 200.

At this time, as illustrated in FIG. 4B, the coupling electrode 31, the metal bonding layer 32, the metal bonding layer 43, the via 44A, the wiring layer 45A, the via 44B, the wiring layer 45B, and the via 44C may be provided in respective substantially rectangular planar shapes that share the same center.

In the example illustrated in FIG. 4B, among the layers of the coupling section 49, the metal bonding layers 32 and 43 each have the largest plane region, and the coupling electrode 31, the via 44A, the wiring layer 45A, the via 44B, the wiring layer 45B, and the via 44C are so provided as to be included inside the plane region of each of the metal bonding layers 32 and 43. This makes it possible for the photodetection device 1 to electrically couple the layers from the photoelectric conversion layer 21 to the diffusion region 47 to each other via a shorter transmission path. Accordingly, it is possible to reduce a magnitude of a wiring capacitance to be generated in the coupling section 49 extending from the photoelectric conversion layer 21 to the diffusion region 47. The photodetection device 1 according to the present embodiment is therefore able to further reduce noise resulting from the wiring capacitance of the coupling section 49.

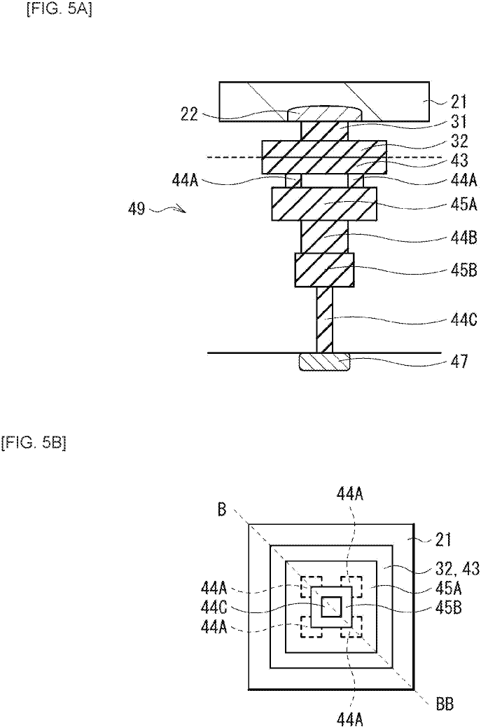

Next, another example of the configuration of the coupling section 49 will be described with reference to FIGS. 5A and 5B. FIG. 5A is a vertical cross-sectional diagram illustrating a cross-sectional configuration of another example of the coupling section 49. FIG. 5B is a planar diagram illustrating a planar configuration of the other example of the coupling section 49. The cross section illustrated in FIG. 5A corresponds to a cross section taken along cut line B-BB of FIG. 5B.

As illustrated in FIG. 5A, the photoelectric conversion layer 21 is electrically coupled to the diffusion region 47 via the coupling section 49. The coupling section 49 is provided by stacking, from the photoelectric conversion layer 21 side, the coupling electrode 31, the metal bonding layer 32, the metal bonding layer 43, a plurality of vias 44A, the wiring layer 45A, the via 44B, the wiring layer 45B, and the via 44C substantially in series in the thickness direction of the first substrate 100 and the second substrate 200.

At this time, as illustrated in FIG. 5B, the metal bonding layer 32, the metal bonding layer 43, the wiring layer 45A, the wiring layer 45B, and the via 44C may be provided in respective substantially rectangular planar shapes that share the same center. Further, the metal bonding layer 43 and the wiring layer 45A may be electrically coupled by four vias 44A provided in correspondence with the four corners of a rectangular shape.

In the example illustrated in FIG. 5B, among the layers of the coupling section 49, the metal bonding layers 32 and 43 each have the largest plane region, and the coupling electrode 31, the plurality of vias 44A, the wiring layer 45A, the via 44B, the wiring layer 45B, and the via 44C are so provided as to be included inside the plane region of each of the metal bonding layers 32 and 43.

In other words, the layers of the coupling section 49 may be electrically coupled to each other by the plurality of vias 44A. Further, the layers of the coupling section 49 may be configured by a plurality of wiring lines separated from each other. In these cases also, the layers of the coupling section 49 are each so provided as to be included inside the plane region of the layer that is largest in plane region. In such a case also, it is possible for the photodetection device 1 to electrically couple the layers from the photoelectric conversion layer 21 to the diffusion region 47 to each other via a shorter transmission path. Accordingly, it is possible to reduce the magnitude of the wiring capacitance to be generated in the coupling section 49 extending from the photoelectric conversion layer 21 to the diffusion region 47. The photodetection device 1 is therefore able to further reduce the noise resulting from the wiring capacitance of the coupling section 49.

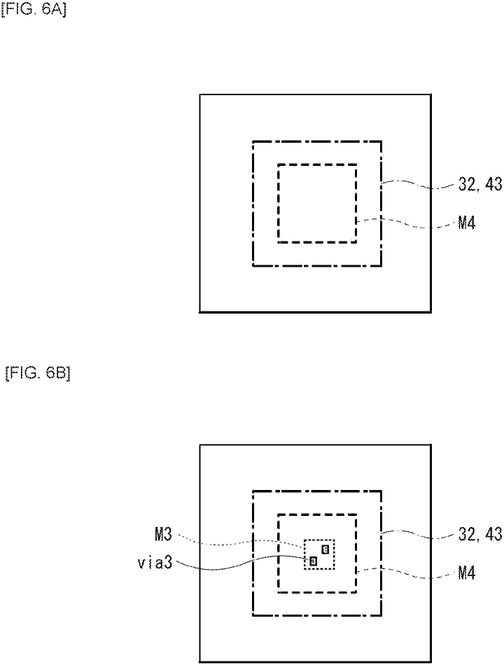

Further, with reference to FIGS. 6A to 6D, a description will be given of a more specific planar shape of each layer of the coupling section 49. FIGS. 6A to 6D are schematic planar diagrams illustrating respective planar shapes of the wiring layers provided in the second substrate 200.

In FIGS. 6A to 6D, the wiring layers 45 provided in the interlayer insulating layer 42 are designated as a first wiring layer M1, a second wiring layer M2, a third wiring layer M3, and a fourth wiring layer M4 from a semiconductor substrate 41 side. Further, the vias 44 provided in the interlayer insulating layer 42 are designated as a first via vial, a second via via2, and a third via via3 from the semiconductor substrate 41 side.

As illustrated in FIG. 6A, the metal bonding layers 32 and 43 having a rectangular shape are provided for each sensor pixel 11. The fourth wiring layer M4 having a rectangular shape is provided inside a rectangular plane region in which the metal bonding layers 32 and 43 are provided. The fourth wiring layer M4 is electrically coupled to the metal bonding layers 32 and 43 by an unillustrated via or the like.

Further, as illustrated in FIG. 6B, the third wiring layer M3 having a rectangular shape is provided inside a rectangular plane region in which the fourth wiring layer M4 is provided. The third wiring layer M3 is electrically coupled to the fourth wiring layer M4 via two third vias via3.

Further, as illustrated in FIG. 6C, the second wiring layer M2 having a long shape is provided across the rectangular shape in which the third wiring layer M3 is provided. The second wiring layer M2 is electrically coupled to the third wiring layer M3 via two second vias via2.

Further, as illustrated in FIG. 6D, the first wiring layer M1 is provided in a plane region overlapping a plane region in which the second wiring layer M2 is provided. The first wiring layer M1 is electrically coupled to the second wiring layer M2 via two first vias vial.

Thus, as illustrated in FIGS. 6A to 6D, the first wiring layer M1, the second wiring layer M2, the third wiring layer M3, and the fourth wiring layer M4 are all provided inside the plane region in which the metal bonding layers 32 and 43 are provided. This allows the photoelectric conversion layer 21 and the diffusion region 47 to be electrically coupled via a transmission path provided in a substantially linear shape in the thickness direction of the first substrate 100 and the second substrate 200. Accordingly, it is possible to reduce the wiring capacitance to be generated in the transmission path.

It is to be noted that while an example in which the metal bonding layers 32 and 43 have the largest plane region among the layers of the coupling section 49 has been illustrated above, the technology according to the present embodiment is not limited to the example illustrated above. The layer having the largest plane region among the layers of the coupling section 49 may be any one of the wiring layers 45.

### 3. Modification Examples

### (First Modification Example)

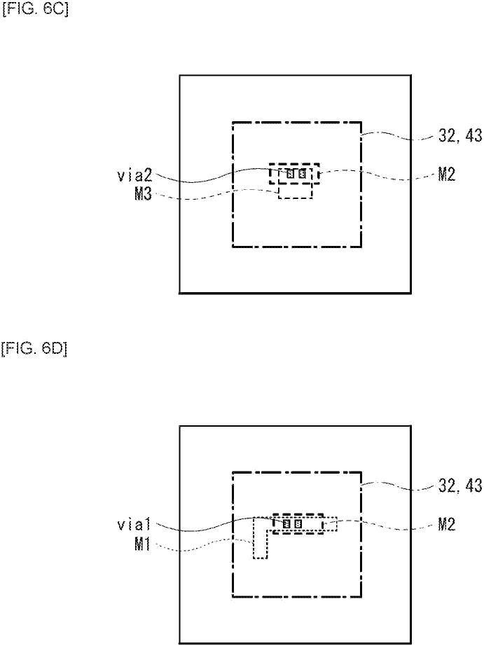

Next, with reference to FIG. 7, a description will be given of a coupling section 49A according to a first modification example. FIG. 7 is a schematic vertical cross-sectional diagram illustrating a configuration of the coupling section 49A according to the first modification example.

As illustrated in FIG. 7, the coupling section 49A is different from the coupling section 49 illustrated in FIG. 4A in that an insulating layer 33, an electrode 37, and a contact electrode 38 are provided instead of the passivation layer 28, the insulating layer 29, and the coupling electrode 31.

The insulating layer 33 is provided to cover one surface of the photoelectric conversion layer 21, and has an opening at a location corresponding to each of the contact layers 22. The insulating layer 33 may include, for example, an insulating material such as silicon oxide (SiOₓ), silicon nitride (SiN), or aluminum oxide (Al₂O₃).

The electrode 37 is provided to fill each of the openings of the insulating layer 33 and to electrically couple to a corresponding one of the contact layers 22. The electrode 37 may include an electrically-conductive material such as palladium (Pd), titanium (Ti), titanium nitride (TiN), tungsten (W), nickel (Ni), aluminum (Al), copper (Cu), platinum (Pt), silver (Ag), or gold (Au).

The contact electrode 38 is provided in correspondence with each of the electrodes 37, and electrically couples the electrode 37 and the metal bonding layer 32. The contact electrode 38 may include an electrically-conductive material such as palladium (Pd), titanium (Ti), titanium nitride (TiN), tungsten (W), nickel (Ni), aluminum (Al), copper (Cu), platinum (Pt), silver (Ag), or gold (Au).

Here, the coupling section 49A is provided by stacking, from the photoelectric conversion layer 21 side, the electrode 37, the contact electrode 38, the metal bonding layer 32, the metal bonding layer 43, the via 44A, the wiring layer 45A, the via 44B, and the wiring layer 45B, and the via 44C substantially in series in the thickness direction of the first substrate 100 and the second substrate 200.

In addition, the coupling section 49A may be provided to allow the metal bonding layers 32 and the 43 to be largest in plane region among the layers of the coupling section 49A. For example, by being provided to cover the pixel drive line 12 or the vertical signal line 13, the metal bonding layers 32 and 43 are able to electrically shield the photoelectric conversion layers 21 of adjacent sensor pixels 11 from the pixel drive line 12 or the vertical signal line 13. This makes it possible for the metal bonding layers 32 and 43 to suppress variations of the potentials of the photoelectric conversion layers 21 of the adjacent sensor pixels 11 caused by a pulse current flowing through the pixel drive line 12 or the vertical signal line 13. Accordingly, it is possible to suppress a decrease in sensitivity or an increase in dark current in the adjacent sensor pixels 11.

### (Second Modification Example)

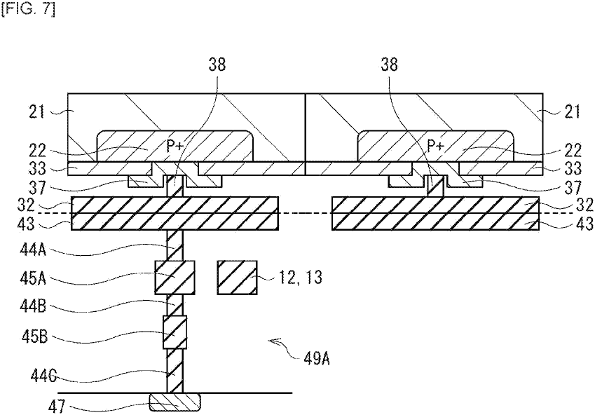

Next, with reference to FIG. 8, a description will be given of a coupling section 49B according to a second modification example. FIG. 8 is a schematic vertical cross-sectional diagram illustrating a configuration of the coupling section 49B according to the second modification example.

As illustrated in FIG. 8, the coupling section 49B is different from the coupling section 49A illustrated in FIG. 7 in that the metal bonding layers 32 and 43 and the wiring layer 45A are so provided as to be largest in plane region among the layers of the coupling section 49B.

As illustrated in FIG. 8, the coupling section 49B is provided by stacking, from the photoelectric conversion layer 21 side, the electrode 37, the contact electrode 38, the metal bonding layer 32, the metal bonding layer 43, the via 44A, the wiring layer 45A, the via 44B, and the wiring layer 45B, and the via 44C substantially in series in the thickness direction of the first substrate 100 and the second substrate 200.

In addition, the coupling section 49B may be provided to allow, among the layers of the coupling section 49B, the metal bonding layers 32 and 43, and the wiring layer 45A directly below the metal bonding layers 32 and 43 to have the same area and to be largest in plane region. In such a case, the metal bonding layers 32 and 43 and the wiring layer 45A are able to suppress, with higher reliability, a pulse current or the like from the wiring layer 45B provided closer to the semiconductor substrate 41 exerting an influence on the photoelectric conversion layers 21 of adjacent sensor pixels 11. Accordingly, it is possible for the coupling section 49D to suppress a decrease in sensitivity or an increase in dark current in the adjacent sensor pixels 11.

### (Third Modification Example)

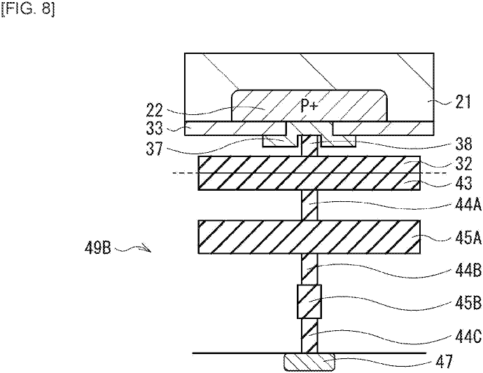

Next, with reference to FIGS. 9 to 12, a description will be given of the sensor pixels 11 according to a third modification example. The sensor pixels 11 according to the third modification example are each different from the sensor pixels 11 illustrated in FIGS. 1 to 3 in circuit configuration of the readout circuit 15. FIGS. 9 to 12 are circuit diagrams illustrating configuration examples of equivalent circuits of the sensor pixels 11 according to the third modification example.

As illustrated in FIG. 9, in a readout circuit 15A of the sensor pixel 11, a source-follower-type amplifier SF is electrically coupled to the diffusion region SN, and a first sample-and-hold circuit SH1 and a second sample-and-hold circuit SH2 are electrically coupled in series to an output end of the source-follower-type amplifier SF.

In the source-follower-type amplifier SF, a drain terminal is electrically coupled to the power supply line VDD, a gate terminal of an input is electrically coupled to the diffusion region SN, and a source terminal of an output is electrically coupled to an input of the first sample-and-hold circuit SH1. The source-follower-type amplifier SF is operable to allow an output voltage to follow an input voltage.

The first sample-and-hold circuit SH1 includes a transistor SAM1 serving as a switch and a capacitor C1 storing electric charge. The first sample-and-hold circuit SH1 is able to hold a voltage in a predetermined timed fashion by storing the electric charge in the capacitor C1.

The second sample-and-hold circuit SH2 includes a transistor SAM2 serving as a switch and a capacitor C2 storing electric charge. The second sample-and-hold circuit SH2 is able to hold a voltage in a predetermined timed fashion by storing the electric charge in the capacitor C2.

The amplification transistor AMP and the selection transistor SEL are electrically coupled to an output end of the second sample-and-hold circuit SH2. Specifically, the gate of the amplification transistor AMP is electrically coupled to the output end of the second sample-and-hold circuit SH2, and the source of the amplification transistor AMP is electrically coupled to the drain of the selection transistor SEL. Upon turning-on of the selection transistor SEL, the amplification transistor AMP is able to amplify a potential held at the second sample-and-hold circuit SH2 and to output a voltage corresponding to the potential of the second sample-and-hold circuit SH2.

In the above-described manner, the readout circuit 15A illustrated in FIG. 9 is able to output a detection signal corresponding to the electric charge stored in the diffusion region SN.

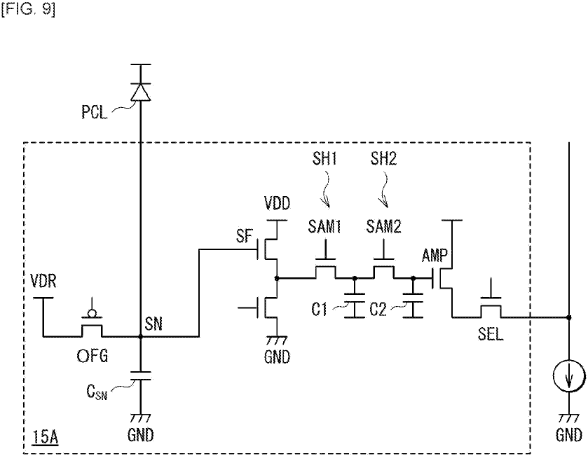

As illustrated in FIG. 10, in a readout circuit 15B of the sensor pixel 11, the source-follower-type amplifier SF is electrically coupled to the diffusion region SN, and the first sample-and-hold circuit SH1 and the second sample-and-hold circuit SH2 are electrically coupled in parallel to the output end of the source-follower-type amplifier SF.

In the source-follower-type amplifier SF, the drain terminal is electrically coupled to the power supply line VDD, the gate terminal of the input is electrically coupled to the diffusion region SN, and the source terminal of the output is electrically coupled to the input of each of the first sample-and-hold circuit SH1 and the second sample-and-hold circuit SH2. The source-follower-type amplifier SF is operable to allow the output voltage to follow the input voltage.

The first sample-and-hold circuit SH1 includes the transistor SAM1 serving as a switch and the capacitor C1 storing electric charge. The first sample-and-hold circuit SH1 is able to hold a voltage in a predetermined timed fashion by storing the electric charge in the capacitor C1. An amplification transistor AMP1 and a selection transistor SEL1 are electrically coupled to an output end of the first sample-and-hold circuit SH1. Upon turning-on of the selection transistor SEL1, the amplification transistor AMP1 is able to amplify a potential held at the first sample-and-hold circuit SH1 and to output a voltage corresponding to the potential of the first sample-and-hold circuit SH1.

The second sample-and-hold circuit SH2 includes the transistor SAM2 serving as a switch and the capacitor C2 storing electric charge. The second sample-and-hold circuit SH2 is similarly able to hold a voltage in a predetermined timed fashion by storing the electric charge in the capacitor C2. An amplification transistor AMP2 and a selection transistor SEL2 are electrically coupled to the output end of the second sample-and-hold circuit SH2. Upon turning-on of the selection transistor SEL2, the amplification transistor AMP2 is able to amplify the potential held at the second sample-and-hold circuit SH2 and to output the voltage corresponding to the potential of the second sample-and-hold circuit SH2.

In the above-described manner, the readout circuit 15B illustrated in FIG. 10 is able to output the detection signal corresponding to the electric charge stored in the diffusion region SN through two separate channels at each timing.

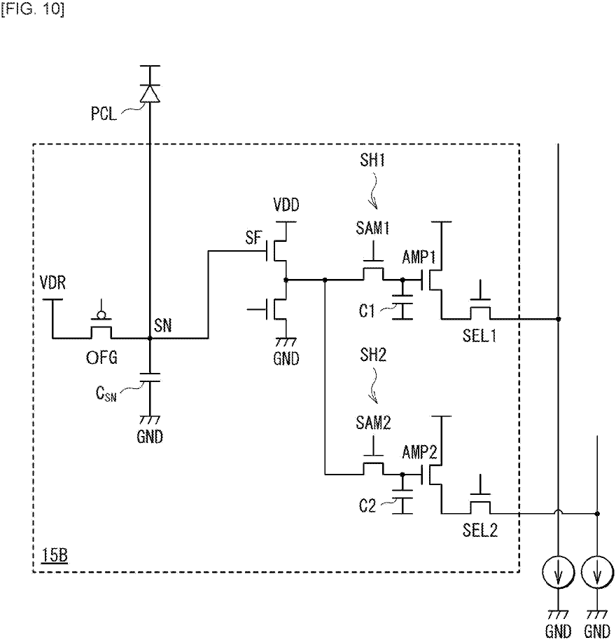

As illustrated in FIG. 11, in a readout circuit 15C of the sensor pixel 11, a CTIA (Capacitive TransImpedance Amplifier) circuit CA is electrically coupled to the diffusion region SN, and the first sample-and-hold circuit SH1 and the second sample-and-hold circuit SH2 are electrically coupled in series to an output end of the CTIA circuit CA.

The CTIA circuit CA includes a capacitor Cfb storing the electric charge stored in the diffusion region SN, an integration circuit IC in which a negative feedback is formed by the capacitor Cfb, and a reset transistor RST for discharging the electric charge stored in the capacitor Cfb. The CTIA circuit CA is able to output an output voltage having a greater amplitude to the first sample-and-hold circuit SH1 in accordance with the electric charge stored in the diffusion region SN.

The first sample-and-hold circuit SH1 includes the transistor SAM1 serving as a switch and the capacitor C1 storing electric charge. The first sample-and-hold circuit SH1 is able to hold a voltage in a predetermined timed fashion by storing the electric charge in the capacitor C1.

The second sample-and-hold circuit SH2 includes the transistor SAM2 serving as a switch and the capacitor C2 storing electric charge. The second sample-and-hold circuit SH2 is able to hold a voltage in a predetermined timed fashion by storing the electric charge in the capacitor C2.

The amplification transistor AMP and the selection transistor SEL are electrically coupled to the output end of the second sample-and-hold circuit SH2. Specifically, the gate of the amplification transistor AMP is electrically coupled to the output end of the second sample-and-hold circuit SH2, and the source of the amplification transistor AMP is electrically coupled to the drain of the selection transistor SEL. Upon turning-on of the selection transistor SEL, the amplification transistor AMP is able to amplify the potential held at the second sample-and-hold circuit SH2 and to output the voltage corresponding to the potential of the second sample-and-hold circuit SH2.

In the above-described manner, the readout circuit 15C illustrated in FIG. 11 is able to output the detection signal corresponding to the electric charge stored in the diffusion region SN.

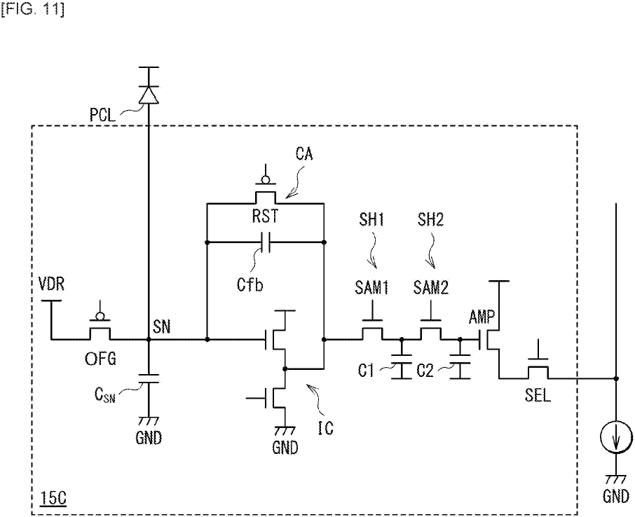

As illustrated in FIG. 12, in a readout circuit 15D of the sensor pixel 11, the CTIA circuit CA is electrically coupled to the diffusion region SN, and the first sample-and-hold circuit SH1 and the second sample-and-hold circuit SH2 are electrically coupled in parallel to the output end of the CTIA circuit CA.

The CTIA circuit CA includes the capacitor Cfb storing the electric charge stored in the diffusion region SN, the integration circuit IC in which the negative feedback is formed by the capacitor Cfb, and the reset transistor RST for discharging the electric charge stored in the capacitor Cfb. The CTIA circuit CA is able to output an output voltage having a greater amplitude to the first sample-and-hold circuit SH1 and the second sample-and-hold circuit SH2 in accordance with the electric charge stored in the diffusion region SN.

The first sample-and-hold circuit SH1 includes the transistor SAM1 serving as a switch and the capacitor C1 storing electric charge. The first sample-and-hold circuit SH1 is able to hold a voltage in a predetermined timed fashion by storing the electric charge in the capacitor C1. The amplification transistor AMP1 and the selection transistor SEL1 are electrically coupled to the output end of the first sample-and-hold circuit SH1. Upon turning-on of the selection transistor SEL1, the amplification transistor AMP1 is able to amplify the potential held at the first sample-and-hold circuit SH1 and to output the voltage corresponding to the potential of the first sample-and-hold circuit SH1.

The second sample-and-hold circuit SH2 includes the transistor SAM2 serving as a switch and the capacitor C2 storing electric charge. The second sample-and-hold circuit SH2 is similarly able to hold a voltage in a predetermined timed fashion by storing the electric charge in the capacitor C2. The amplification transistor AMP2 and the selection transistor SEL2 are electrically coupled to the output end of the second sample-and-hold circuit SH2. Upon turning-on of the selection transistor SEL2, the amplification transistor AMP2 is able to amplify the potential held at the second sample-and-hold circuit SH2 and to output the voltage corresponding to the potential of the second sample-and-hold circuit SH2.

In the above-described manner, the readout circuit 15D illustrated in FIG. 12 is able to output the detection signal corresponding to the electric charge stored in the diffusion region SN through two separate channels at each timing.

### 4. Application Example

The technology according to the present disclosure is applicable in general to any electronic apparatus that includes an imaging unit, such as a camera module including an optical lens system or the like, an imaging unit such as a digital still camera or a video camera, a mobile terminal unit (e.g., a smartphone or a tablet terminal) having an imaging function, or a copying machine in which an imaging unit is used as an image reading section.

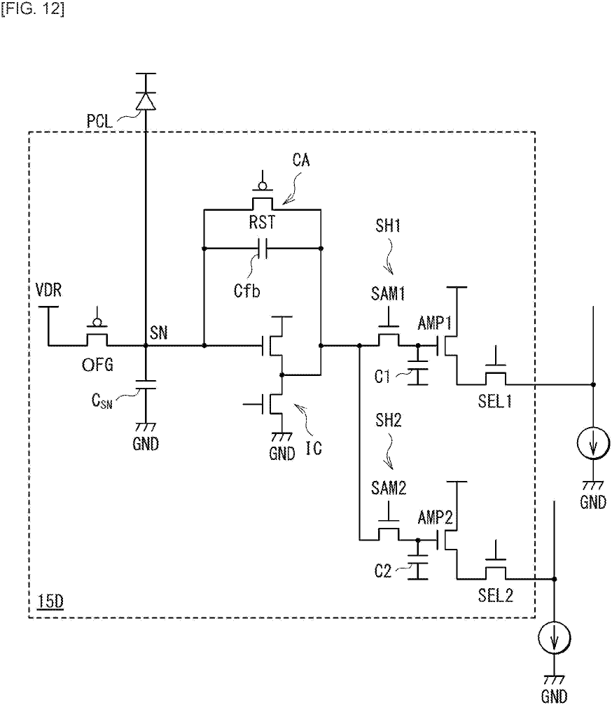

FIG. 13 is a block diagram illustrating an example of a schematic configuration of an imaging unit 3 including the photodetection device 1 according to the present embodiment.

The imaging unit 3 is, for example, an electronic apparatus. Examples of the electronic apparatus include an imaging unit such as a digital still camera or a video camera, and a mobile terminal unit such as a smartphone or a tablet terminal. The imaging unit 3 includes, for example, the photodetection device 1, an optical system 141, a shutter device 142, a DSP circuit 143, a frame memory 144, a display section 145, a storage section 146, an operation section 147, and a power supply section 148. In the imaging unit 3, the photodetection device 1, the shutter device 142, the DSP circuit 143, the frame memory 144, the display section 145, the storage section 146, the operation section 147, and the power supply section 148 are coupled to each other via a bus line 149.

The photodetection device 1 outputs image data (a digital value) corresponding to entering light. The optical system 141 includes one or more lenses, and guides light from a subject to the photodetection device 1 to form an image on the light-receiving surface of the photodetection device 1. The shutter device 142 is disposed between the optical system 141 and the photodetection device 1, and controls a period during which the photodetection device 1 is to be irradiated with light and a period during which the light is to be blocked. The DSP circuit 143 is a signal processing circuit that performs signal processing on the image data (the digital value) outputted from the photodetection device 1. The frame memory 144 temporarily holds the image data processed by the DSP circuit 143 on a frame-by-frame basis. The display section 145 includes, for example, a panel-type display such as a liquid crystal panel or an organic EL (Electro Luminescence) panel, and displays a moving image or a still image captured by the photodetection device 1. The storage section 146 stores image data of the moving image or the still image captured by the photodetection device 1 in a recording medium such as a semiconductor memory or a hard disk. The operation section 147 outputs an operation command for various functions of the imaging unit 3 in accordance with an operation performed by a user. The power supply section 148 is a power supply for operation of the photodetection device 1, the shutter device 142, the DSP circuit 143, the frame memory 144, the display section 145, the storage section 146, and the operation section 147. The power supply section 148 appropriately supplies electric power to these supply targets.

Next, a description will be given of an imaging procedure of the imaging unit 3.

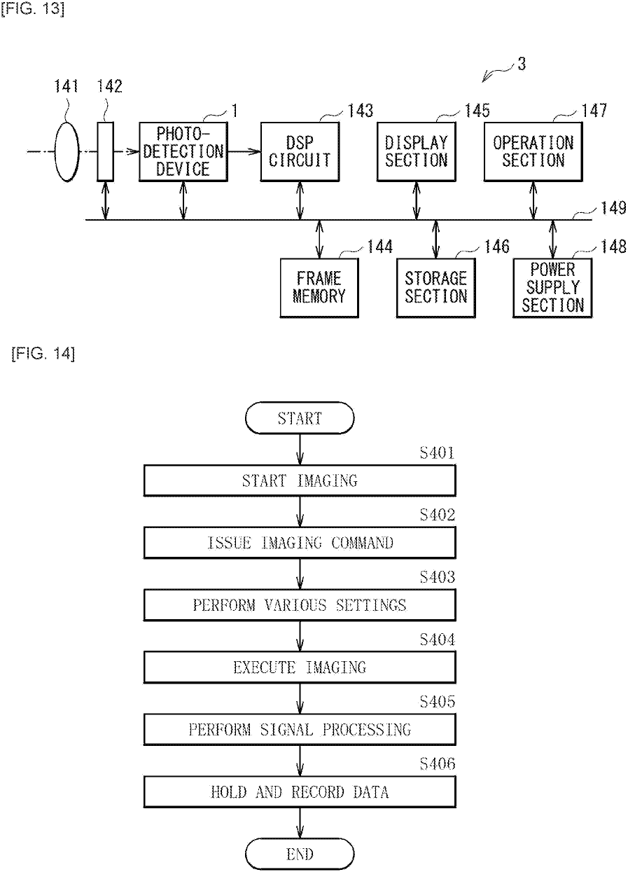

FIG. 14 illustrates an example of a flowchart of an imaging operation of the imaging unit 3.

First, a user issues an instruction to start imaging by operating the operation section 147 (S401). Next, the operation section 147 outputs an imaging instruction to the photodetection device 1 (S402). Having received the imaging instruction, the photodetection device 1 then performs various settings (S403) and thereafter executes imaging in a predetermined imaging scheme (S404). It is to be noted that in the imaging unit 3, the photodetection device 1 may perform the operations of step S403 and step S404 repeatedly on an as-needed basis.

Thereafter, the photodetection device 1 outputs image data obtained through imaging to the DSP circuit 143. Here, the image data refers to data of the detection signals for all pixels that are generated on the basis of the electric charge temporarily held by the floating diffusion FD. The DSP circuit 143 performs predetermined signal processing (e.g., noise reduction processing or the like) on the basis of the image data inputted from the photodetection device 1 (S405). Next, the DSP circuit 143 causes the frame memory 144 to hold the image data that has undergone the predetermined signal processing, and the frame memory 144 stores the image data in the storage section 146 (S406). The imaging unit 3 performs imaging through the operations described above.

The technology according to the present disclosure has been described above with reference to the embodiments and the modification examples. However, the technology according to the present disclosure is not limited to the above-described embodiments and the like, and is modifiable in a variety of ways.

In addition, not all of the configurations and the operations described in the embodiments and the modification examples are indispensable as the configurations and the operations of the present disclosure. For example, among the components of the embodiments and the modification examples, any component that is not recited in an independent claim which represents the most generic concept of the present disclosure is to be understood as an optional component.

Terms used throughout this specification and the appended claims should be construed as “non-limiting” terms. For example, the term “including” or “included” should be construed as “not limited to what is described as being included”. The term “having” should be construed as “not limited to what is described as being had”.

The terms used herein include terms that are used merely for convenience of description and that are not used to limit the configuration and the operation. For example, the terms such as “right”, “left”, “upper”, and “lower” only indicate directions in the drawings being referred to. In addition, the terms “inside” and “outside” only indicate a direction toward the center of a component of interest and a direction away from the center of a component of interest, respectively. The same applies to terms similar to these and to terms with the similar purpose.

It is to be noted that the technology according to the present disclosure may have the following configurations. The technology according to the present disclosure having the following configurations allows for reduction of the magnitude of the wiring capacitance to be generated in the coupling section extending from the photoelectric conversion layer to the diffusion region. Accordingly, the photodetection device makes it possible to reduce the noise resulting from the wiring capacitance of the coupling section. Effects attained by the technology according to the present disclosure are not necessarily limited to the effects described herein, and may include any of the effects described in the present disclosure.

A photodetection device including:
a photoelectric conversion layer provided in a first substrate;
a diffusion region provided in a second substrate attached to the first substrate, the diffusion region storing electric charge resulting from photoelectric conversion at the photoelectric conversion layer; and
a coupling section having a multilayer structure including a via and a wiring layer, the coupling section being provided to extend from the first substrate to the second substrate and electrically coupling the photoelectric conversion layer and the diffusion region, in which
the coupling section is provided in a manner in which, as viewed in a plane from a direction normal to a principal surface of each of the first substrate and the second substrate, a plane region of each layer is included in a plane region of a layer that is largest in plane region.

The photodetection device according to (1), in which the coupling section further includes a metal bonding layer provided in a bonding surface between the first substrate and the second substrate.

The photodetection device according to (2), in which the layer that is largest in plane region includes the metal bonding layer.

The photodetection device according to (2), in which the layer that is largest in plane region includes the wiring layer and the metal bonding layer, the wiring layer being provided on a side of the metal bonding layer closer to the second substrate and directly below the metal bonding layer.

The photodetection device according to any one of (2) to (4), in which the metal bonding layer includes a Cu-Cu bonding layer.

The photodetection device according to any one of (1) to (5), in which the coupling section further includes an electrode provided for each pixel and in contact with the photoelectric conversion layer.

The photodetection device according to any one of (1) to (6), in which each of a plurality of the wiring layers has a rectangular shape.

The photodetection device according to any one of (1) to (7), in which at least one or more of a plurality of the wiring layers are electrically coupled by another of the wiring layers and a plurality of the vias.

The photodetection device according to any one of (1) to (8), in which the photoelectric conversion layer includes InGaAs.

The photodetection device according to any one of (1) to (9), in which the electric charge stored in the diffusion region is outputted to a readout circuit that converts the electric charge into a pixel signal.

The photodetection device according to (10), in which the readout circuit includes a readout circuit of a floating-diffusion-holding type.

An electronic apparatus including:
a photoelectric conversion layer provided in a first substrate;
a diffusion region provided in a second substrate attached to the first substrate, the diffusion region storing electric charge resulting from photoelectric conversion at the photoelectric conversion layer; and
a coupling section having a multilayer structure including a via and a wiring layer, the coupling section being provided to extend from the first substrate to the second substrate and electrically coupling the photoelectric conversion layer and the diffusion region, in which
the coupling section is provided in a manner in which, as viewed in a plane from a direction normal to a principal surface of each of the first substrate and the second substrate, a plane region of each layer is included in a plane region of a layer that is largest in plane region.

This application claims priority based on Japanese Patent Application No. 2020-111983 filed on Jun. 29, 2020 with Japan Patent Office, the entire contents of which are incorporated in this application by reference.

It should be understood by those skilled in the art that various modifications, combinations, sub-combinations and alterations may occur depending on design requirements and other factors insofar as they are within the scope of the appended claims or the equivalents thereof.

1. A photodetection device comprising:
a photoelectric conversion layer provided in a first substrate;
a diffusion region provided in a second substrate attached to the first substrate, the diffusion region storing electric charge resulting from photoelectric conversion at the photoelectric conversion layer; and
a coupling section having a multilayer structure including a via and a wiring layer, the coupling section being provided to extend from the first substrate to the second substrate and electrically coupling the photoelectric conversion layer and the diffusion region, wherein
the coupling section is provided in a manner in which, as viewed in a plane from a direction normal to a principal surface of each of the first substrate and the second substrate, a plane region of each layer is included in a plane region of a layer that is largest in plane region.

2. The photodetection device according to claim 1, wherein the coupling section further includes a metal bonding layer provided in a bonding surface between the first substrate and the second substrate.

3. The photodetection device according to claim 2, wherein the layer that is largest in plane region comprises the metal bonding layer.

4. The photodetection device according to claim 2, wherein the layer that is largest in plane region comprises the wiring layer and the metal bonding layer, the wiring layer being provided on a side of the metal bonding layer closer to the second substrate and directly below the metal bonding layer.

5. The photodetection device according to claim 2, wherein the metal bonding layer includes a Cu-Cu bonding layer.

6. The photodetection device according to claim 1, wherein the coupling section further includes an electrode provided for each pixel and in contact with the photoelectric conversion layer.

7. The photodetection device according to claim 1, wherein each of a plurality of the wiring layers has a rectangular shape.

8. The photodetection device according to claim 1, wherein at least one or more of a plurality of the wiring layers are electrically coupled by another of the wiring layers and a plurality of the vias.

9. The photodetection device according to claim 1, wherein the photoelectric conversion layer includes InGaAs.

10. The photodetection device according to claim 1, wherein the electric charge stored in the diffusion region is outputted to a readout circuit that converts the electric charge into a pixel signal.

11. The photodetection device according to claim 10, wherein the readout circuit comprises a readout circuit of a floating-diffusion-holding type.

12. An electronic apparatus comprising:
a photoelectric conversion layer provided in a first substrate;
a diffusion region provided in a second substrate attached to the first substrate, the diffusion region storing electric charge resulting from photoelectric conversion at the photoelectric conversion layer; and
a coupling section having a multilayer structure including a via and a wiring layer, the coupling section being provided to extend from the first substrate to the second substrate and electrically coupling the photoelectric conversion layer and the diffusion region, wherein
the coupling section is provided in a manner in which, as viewed in a plane from a direction normal to a principal surface of each of the first substrate and the second substrate, a plane region of each layer is included in a plane region of a layer that is largest in plane region.
